(19) United States
(12) Patent Application Publication
(10) Pub. No.: US 2025/0079388 A1
(43) Pub. Date: Mar. 6, 2025

(54) INTEGRATED CIRCUIT HAVING IMPROVED BALL BONDING ADHESION

(71) Applicant: TEXAS INSTRUMENTS INCORPORATED, DALLAS, TX (US)

(72) Inventors: JOHN CARLO CRUZ MOLINA, Bataan (PH); ANICETO RABILAS, JR., ANGELES (PH); RAY FREDRIC DE ASIS, MABALACAT (PH)

(21) Appl. No.: 18/458,794

(22) Filed: Aug. 30, 2023

(51) Int. Cl. H01L 23/00; H01L 21/56; H01L 23/31

(52) U.S. Cl. CPC H01L 24/48; H01L 21/56; H01L 23/3121; H01L 24/03; H01L 24/05; H01L 24/32; H01L 24/73; H01L 24/92; H01L 2224/03462; H01L 2224/03614; H01L 2224/04042; H01L 2224/05557; H01L 2224/32245; H01L 2224/48245; H01L 2224/48465; H01L 2224/73265; H01L 2224/92247

(57) ABSTRACT

An electronic device includes a substrate and a die having an active surface disposed on the substrate. Bond pads are disposed on the active surface of the die and includes a recess defined in a top surface of the bond pads. Ball bonds are disposed in the recess of the bond pads and wire bonds are attached to the ball bonds and to the substrate. A mold compound encapsulates the die, the bond pads, the ball bonds, and the wire bonds. The mold compound covers all but one surface of the substrate, where the one surface not covered faces away from the die.

### TECHNICAL FIELD

The present disclosure relates to an electronic device and more specifically, to an integrated circuit package that includes an increased ball bonding surface area to improve adhesion.

### BACKGROUND

Leaded and non-leaded integrated circuits include wire bonds that provide a connection between a die and leads of a leadframe. The wire bonds are bonded or secured to an active surface of the die via ball bonds. During attachment of the wire bonds and curing processes, however, stresses occur at a bond line, i.e., at the interface between the ball bond and a bonding surface (e.g., bond pad) on a surface of the die. The stresses result in cracking around a perimeter of the ball bond. As a result, gaps are formed around the perimeter of the ball bond at the bond line thereby compromising the structural integrity and operation of the integrated circuit.

### SUMMARY

In described examples, an electronic device includes a substrate and a die having an active surface disposed on the substrate. Bond pads are disposed on the active surface of the die. The bond pads include a recess defined in a top surface of the bond pads. Ball bonds are disposed in the recess of the bond pads and wire bonds are attached to the ball bonds and to the substrate. A mold compound encapsulates the die, the bond pads, the ball bonds, and the wire bonds. In addition, the mold compound covers all but one surface of the substrate, where the one surface not covered faces away from the die.

In another described example, a method includes providing a die having an active surface and forming bond pads on the active surface of the die. A recess is formed in a top surface of the bond pads. The die is placed on a substrate and wire bonds are attached from the bond pads to the substrate. A mold compound is formed over the die.

In still another described example, a method includes fabricating a die assembly that includes providing a die having an active surface and forming a photoresist material layer over the active surface of the die where the photoresist material layer includes openings patterned therein. A metal plating layer is deposited in the openings of the photoresist material layer to form bond pads on the active surface of the die. A recess is formed in a top surface of the bond pads. The die is placed on a die pad of a leadframe and wire bonds are attached from the bond pads to the leadframe. A mold compound is formed over the die.

### BRIEF DESCRIPTION OF THE DRAWINGS

FIG. 1A is a cross section view of an example electronic device.

FIG. 1B is a close-up view of a bond pad from the example electronic device of FIG. 1A.

FIG. 2 is a block diagram flow chart illustrating a fabrication process for the electronic device of FIG. 1A.

FIG. 3A is a top view of a wafer that includes dies.

FIG. 3B illustrates a cross sectional view of a singulated die from the wafer in FIG. 3A in the early stages of fabrication of a die assembly.

FIG. 3C illustrates a cross sectional view of the die assembly of FIG. 3B undergoing a photoresist material layer patterning.

FIG. 3D illustrates a cross sectional view of the die assembly of FIG. 3C undergoing an electroplating process.

FIG. 3E illustrates a cross sectional view of the die assembly of FIG. 3D after removal of the photoresist material layer.

FIG. 3F illustrates a cross section view of the die assembly of FIG. 3E after undergoing an etch process.

FIG. 3G illustrates a cross section view of a leadframe based substrate in the early stages of assembly of an electronic device.

FIG. 3H illustrates a cross section view of the leadframe based substrate of FIG. 3G after deposition of a die attach material.

FIG. 3I illustrates a cross section view of the electronic device with the die assembly of FIG. 3F attached to the leadframe.

FIG. 3J illustrates a cross section view of the electronic device of FIG. 3I after undergoing a wire bonding process.

FIG. 3K illustrates a cross section view of the electronic device of FIG. 3J after undergoing formation of a mold compound.

FIGS. 4A-4E illustrate a process to attach wire bonds to a die and terminal leads using a capillary instrument.

FIGS. 5A-5C are illustrations of an example single inner chamfered capillary tip configuration.

FIGS. 6A-6C are illustrations of an example double inner chamfered capillary tip configuration.

FIGS. 7A-7C are illustrations of an example convex-shaped inner chamfered capillary tip configuration.

### DETAILED DESCRIPTION

Wire bonds in an integrated circuit (IC) provide a connection between a die and leads of a leadframe. The wire bonds are bonded or secured to an active surface of the die via ball bonds. During wire bonding and curing processes, however, stresses occur at a bond line, i.e., at the interface between the ball bond and a bonding surface (e.g., bond pad) on a surface of the die. The stresses result in cracking around a perimeter of the ball bond. As a result, gaps are formed around the perimeter of the ball bond at a bond line thereby compromising the structural integrity and operation of the integrated circuit.

Disclosed herein is an electronic device (e.g., integrated circuit package) that includes an increased ball bonding surface area, and a method of bonding a ball bond to a bond pad to improve adhesion between the ball bond and the die thereby reducing cracking and thus overcoming the aforementioned disadvantages. The electronic device includes a die attached to a leadframe and bond pads disposed on an active surface of the die. A surface of the bond pads is modified to increase an area of adhesion between the ball bond and the bond pad. Specifically, a recess or cavity is formed in the surface of the bond pads. The formation of the recess increases the bond pad surface area that the ball bond can adhere to after a wire bonding process. Specifically, during the wire bonding process the ball bond is deposited in the recess and is subjected to heat and pressure. As a result, the ball bond adheres to a bottom surface and side walls of the recess.

The method includes using an improved capillary tip configuration to attach wire bond wires to the bond pad, and implementing a low temperature wire bonding process to adhere the ball bond to the bond pad. The improved capillary tip configuration is comprised of either a dual inner chamfer or a convex-shaped inner chamfer. The improved capillary tip distributes force vectors generated by the deposition of the ball bond more uniformly across the ball bond. The uniform distribution of force vectors forces the ball bond more evenly into the recess thereby mitigating the formation of gaps between the ball bond and the bond pad.

The method further includes providing a low wire bonding temperature during the wire bonding process. Current methods use a high wire bonding temperature (e.g., approximately 180° C.), which contributes to the cracking and the gaps at the bond line mentioned above. The method disclosed herein uses a low wire bonding temperature (e.g., less than 120° C.). Since the ball bonds may be copper plated, the low wire bonding temperature mitigates oxidation.

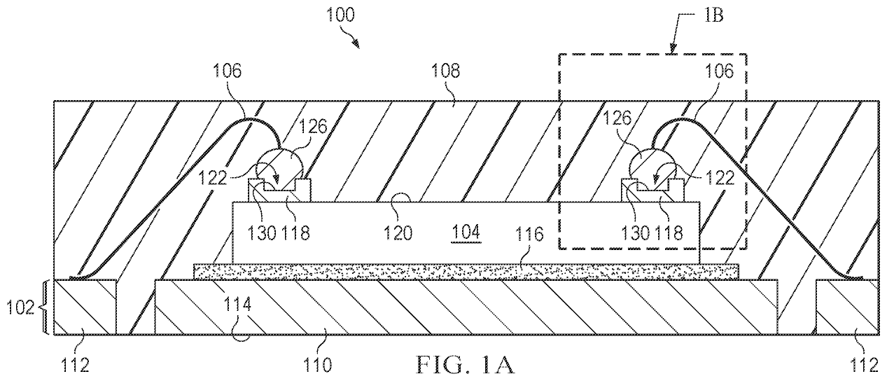

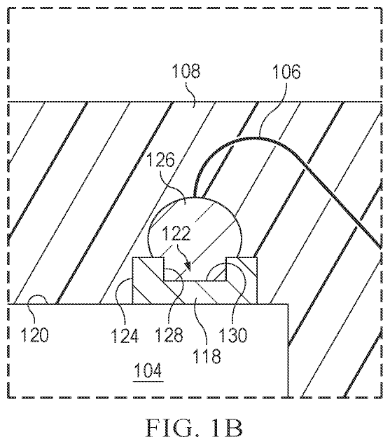

FIG. 1A is a cross-section view of an example electronic device (e.g., integrated circuit) 100 comprised of a substrate 102, a die 104 disposed on the substrate 102, wire bonds 106, and a mold compound 108. The electronic device 100 can be comprised of a leaded or non-leaded integrated circuit (IC) including, but not limited to a Quad Flat No-Lead (QFN) package, a Quad-Flat Package (QFP), Dual In-Line Package (DIP), Single In-Line Package (SIP), etc. Although, the example electronic device 100 in FIG. 1A is an example illustration of a QFN package, the electronic device 100 illustrated in FIG. 1A is for illustrative purposes only and is not intended to limit the scope of the invention.

The substrate 102 is comprised of a leadframe that includes a die pad 110 and conductive terminals 112 (e.g., leads, contacts). In alternative examples, the substrate may be comprised of a laminate substrate or a printed circuit board based substrate. For illustrative purposes only, a leadframe based substrate will be described herein and illustrated in the drawings. The die pad 110 may be comprised of a thermal pad that is exposed on an attachment side 114 of the electronic device 100. The thermal pad creates an efficient heat path away from the electronic device 100 to a board (e.g., printed circuit board). In addition, the exposed thermal pad or die pad 110 also enables a ground connection to the board. The die 104 attaches to the die pad 110 via a die attach material 116.

Still referring to FIG. 1A and also to FIG. 1B, bond pads 118 are disposed on an active surface 120 of the die 104. FIG. 1B is a close-up view of one of the bond pads 118 attached to the active surface 120 of the die 104. The bond pads 118, which are made from copper or aluminum, provide a connection for the wire bonds 106 to the die 104. A recess or cavity 122 is formed in the bond pad 118 thereby forming side walls 124 in the bond pad 118. The recess 122 is configured to receive a ball bond (e.g., melted/molten wire bond material) 126. The recess 122 increases a surface area of the bond pad 118 to increase the bonding adhesion between the bond pad 118 and the ball bond 126. More specifically, the ball bond 126 not only adheres to a top surface of the bond pad 118 and to a bottom surface of the recess 122, the ball bond 126 also adheres to an inner surface 128 of the side walls 124. Thus, the inner surface 128 of the side walls provides additional bond pad surface area for adhesion of the ball bond 126. The additional surface area provided by the recess 122 mitigates the occurrence of gaps at the bond line (i.e., at an interface between the ball bond 126 and the bond pad 118) 130.

The wire bonds 106 are connected to the ball bonds 126 and provide a connection between the active surface 120 of the die 104 and the conductive terminals 112. In the illustrated example, the mold compound 108 covers all but one surface of the substrate 102, where the one surface not covered faces away from the die 104 and the electronic device 100. In addition, the mold compound 108 encapsulates the die 104, the wire bonds 106, the bond pads 118 and the ball bonds 126.

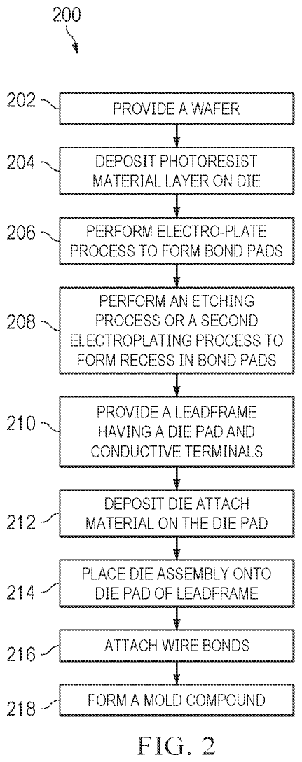

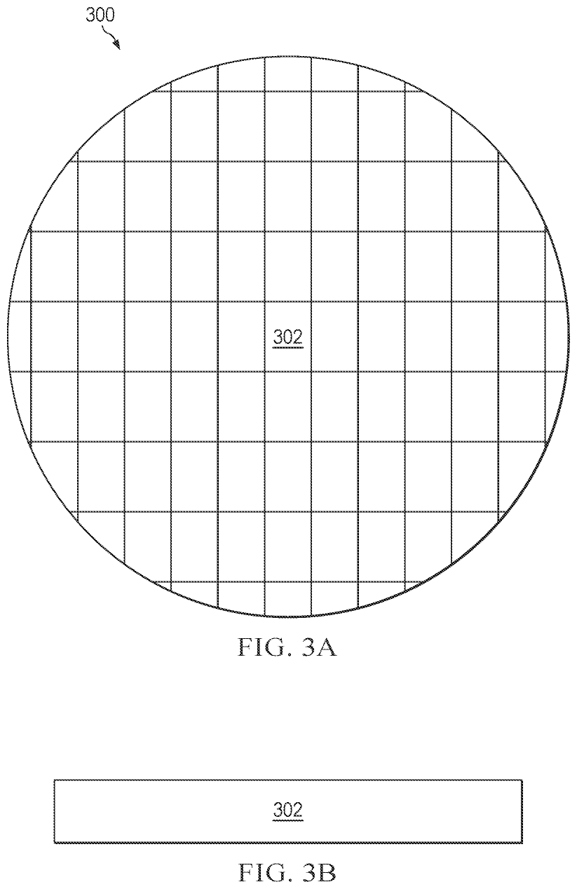

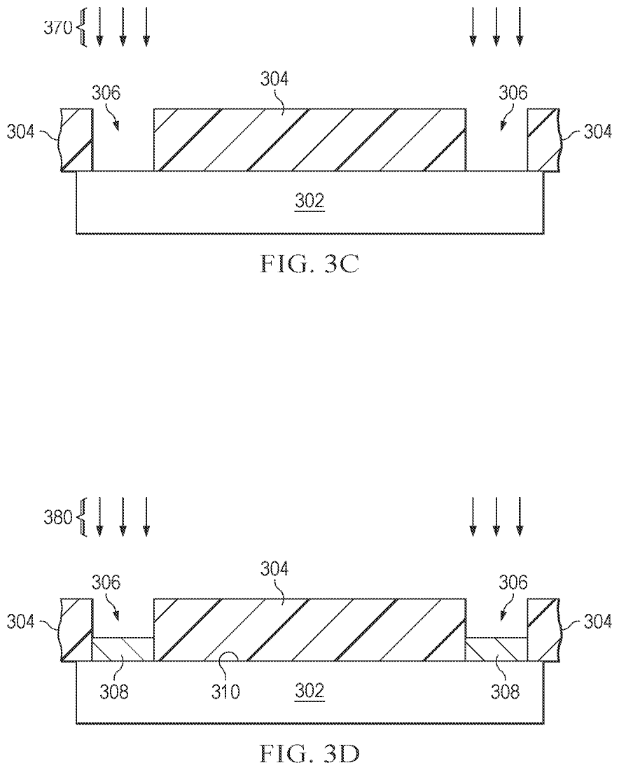

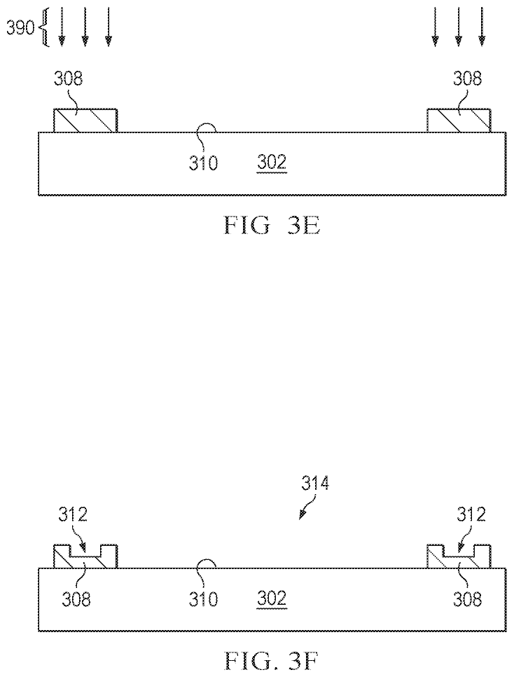

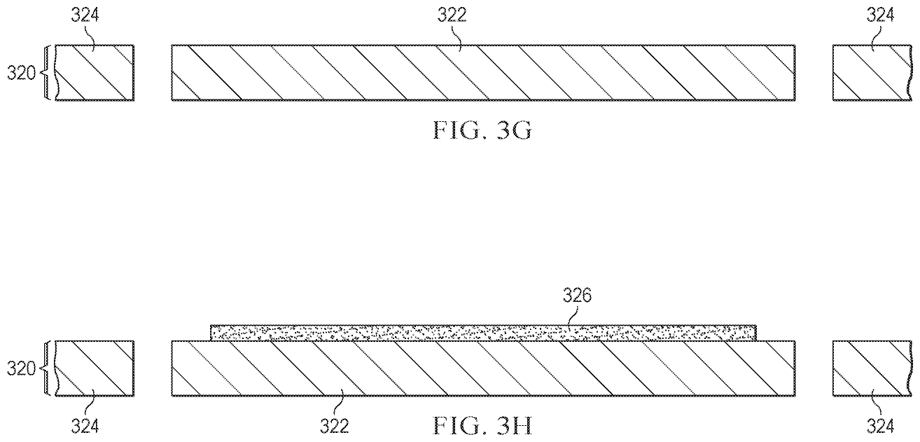

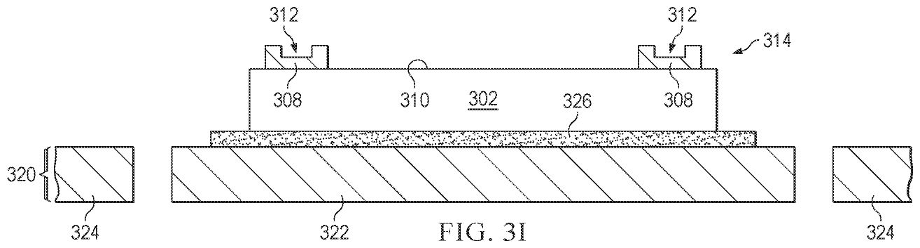

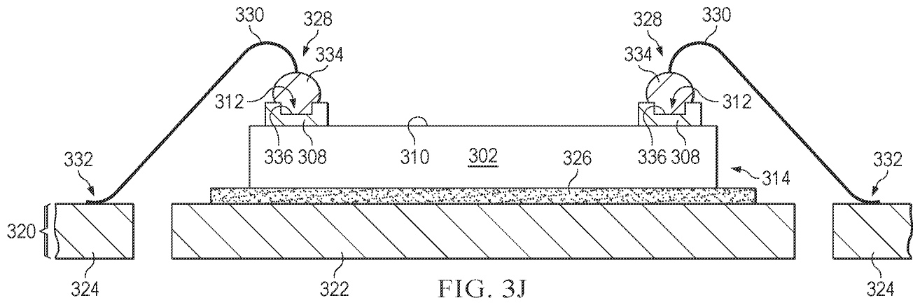

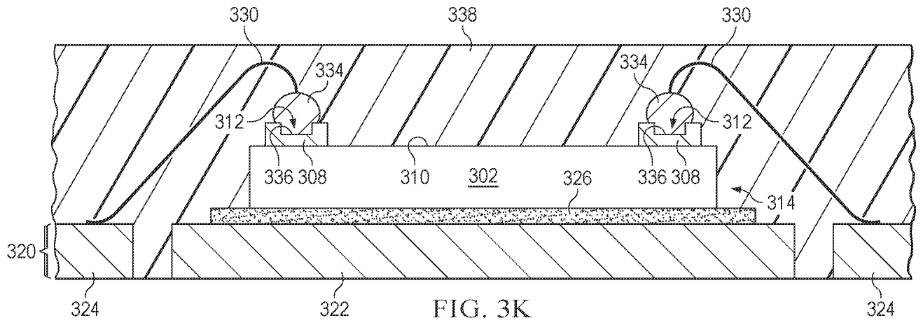

FIG. 2 is a block diagram flow chart explaining a fabrication process 200 and FIGS. 3A-3K illustrate a fabrication process associated with the formation of the electronic device 100 illustrated in FIG. 1A. Specifically, FIGS. 3A-3D illustrate a fabrication process associated with the formation of a die assembly for the electronic device 100 illustrated in FIG. 1A and FIGS. 3G-3K illustrate a fabrication process associated with the process of placing the die assembly on a substrate and a molding process to thereby fabricate the electronic device 100 illustrated in FIG. 1A. Though depicted sequentially as a matter of convenience, at least some of the actions shown can be performed in a different order and/or performed in parallel. Alternatively, some implementations may perform only some of the actions shown. Still further, although the example illustrated in FIGS. 2-3K is an example method illustrating the example configuration of FIG. 1A, other methods and configurations are possible. It is understood that although the method illustrated in FIGS. 2-3K depicts the fabrication process of a single electronic device, the process applies to an array electronic devices. Thus, after fabrication of the array of electronic devices the array is singulated to separate each electronic device 100 from the array.

Referring to FIG. 2 and to FIGS. 3A-3F, the fabrication process of a die assembly for the electronic device 100 illustrated in FIG. 1A begins at 202 with a wafer 300, as illustrated in FIG. 3A. Specifically, FIG. 3A is a schematic diagram of a wafer 300, in accordance with various examples. For example, the wafer 300 may be a silicon wafer. The wafer 300 comprises multiple dies 302. The manufacturing techniques described below may be performed on individual dies 302 (post-singulation), or the techniques may be more efficiently performed on a mass scale, e.g., simultaneously on multiple dies 302 of the wafer 300 (pre-singulation). For convenience and clarity, the remaining drawings show one die 302, with the understanding that the processes described herein as being performed on the die 302 may also be performed (e.g., sequentially performed, simultaneously performed) on the remaining dies 302 of the wafer 300.

FIG. 3B illustrates a cross section view of a single die 302 of the wafer 300. Referring to FIG. 3C, at 204 a photoresist material layer 304 overlies the die 302 and is patterned and developed to expose openings 306 in the photoresist material layer 304 in accordance with a pattern. The photoresist material layer 304 can have a thickness that varies in correspondence with the wavelength of radiation used to pattern the photoresist material layer 304. The photoresist material layer 304 may be formed over the die 302 via spin-coating or spin casting deposition techniques, selectively irradiated (e.g., via deep ultraviolet (DUV) irradiation) and developed to form the openings 306.

At 206, the configuration in FIG. 3C undergoes an electro-plating process 370 to deposit a metal plating layer (e.g., copper, aluminum) in the openings 306 to form bond pads 308 on an active surface 310 of the die 302 resulting in the configuration in FIG. 3D. Once the plating process 370 is complete, the photoresist material layer 304 is removed via a solvent stripping process 380 resulting in the configuration of FIG. 3E. At 208, the configuration in FIG. 3E undergoes and etching process 390 to form a recess or cavity 312 in each bond pad 308 resulting in the configuration in FIG. 3F. Alternatively, the configuration in FIG. 3E can undergo an additional (second) plating process to build up side walls of the bond pads 308 to form the recess 312. The configuration in FIG. 3F represents a single die assembly 314 that includes the die 302 and the bond pads 308 with the recess 312.

FIGS. 3G-3K illustrate a fabrication process associated with the process of placing the die assembly 314 on a substrate and a molding process to thereby fabricate the electronic device 100 illustrated in FIG. 1. In the following description, the substrate is comprised of a leadframe. It is to be understood that in alternative examples, the substrate may be comprised of a laminate substrate or a printed circuit board based substrate. For illustrative purposes only, a leadframe based substrate will be described herein and illustrated in the drawings.

Still referring to FIG. 2, at 210, a leadframe 320 is provided as illustrated in the cross-sectional view of FIG. 3G. The leadframe 320 includes a die pad 322 and conductive terminals 324 (e.g., leads, contacts). At 212, a die attach material 326 is deposited on a surface of the die pad 322 resulting in the configuration in FIG. 3H. For simplicity the dispensed die attach technique is referenced, however, other die attach techniques such as using a die attach film pre applied to the back of the wafer can also be utilized. At 214, the die assembly 314 is then picked and placed on the die attach material 326 resulting in the configuration in FIG. 3I.

At 216, using a capillary instrument described below, a first end 328 of wire bonds 330 is attached via a ball bond (e.g., melted/molten wire bond material) 334 into the recess 312 of the bond pads 308 disposed on the active surface 310 of the die 302 and a second end 332 of the wire bonds 330 is attached to a surface of each of the conductive terminal 324 (e.g., melted/molten wire bond material) resulting in the configuration in FIG. 3J. The wire bonding process is a welding type operation that utilizes heat and pressure to attach the wire bonds 330. More specifically, the wire bonds 330 and ball bonds 334 are heated to a predetermined wire bonding temperature during the wire bonding process. The predetermined wire bonding temperature is a low temperature (e.g., approximately 90° C.-120° C.) that mitigates oxidation occurring to the ball bonds 334 as the ball bonds 334 may be copper plated. During the wire bonding process, as the ball bond 334 is heated, pressure from the capillary instrument described below forces the ball bond 334 into and around the recess 312 to form a bond line 336 (i.e., at an interface between the ball bond 334 and the bond pad 308). During this process, the ball bond 334 will adhere to a bottom surface of the recess 312 and to an inner surface of side walls of the recess 312. The ball bond 334 will also adhere to a top surface of the bond pads 308 adjacent to the recess 312. Thus, the recess 312 increases a surface area of the bond pads 308 to provide adhesion for the ball bond 334.

At 218, a mold compound 338 is formed over the die assembly 314. The mold compound 338 encapsulates the die 302 including the bond pads 308, the ball bonds 334, and the wire bonds 330 resulting in the configuration of FIG. 3K. In the illustrated example, the mold compound 338 covers all but one surface of the leadframe 320, where the one surface not covered faces away from the die assembly 314.

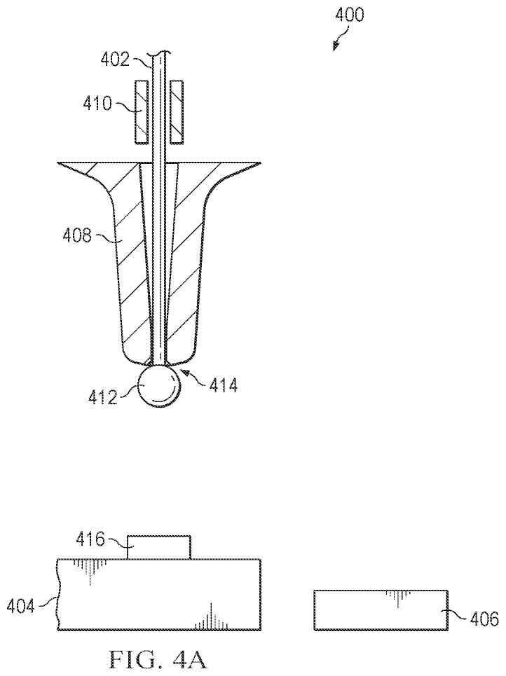

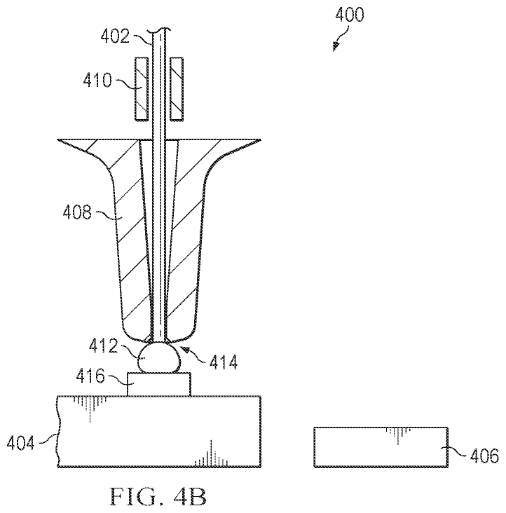

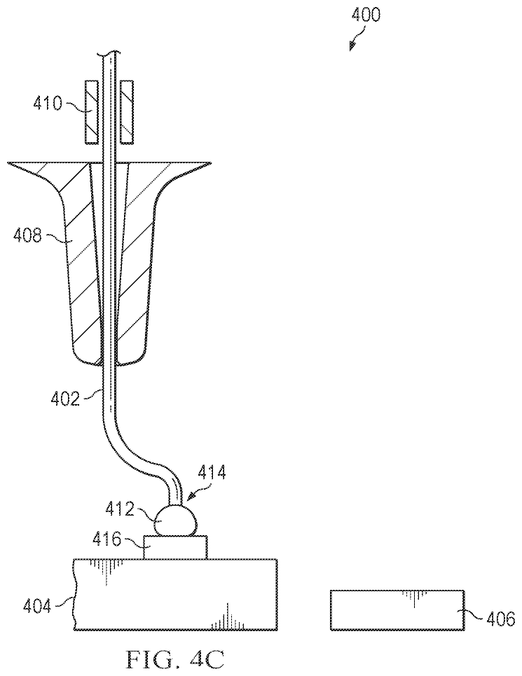

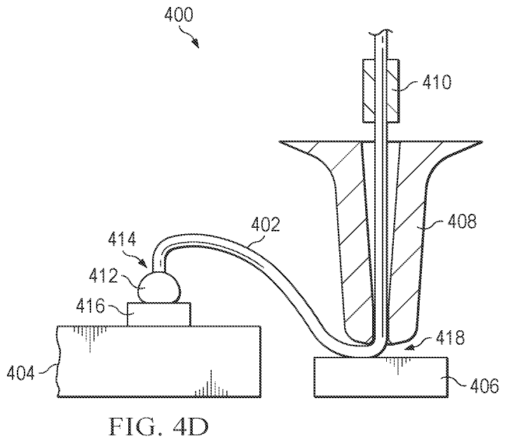

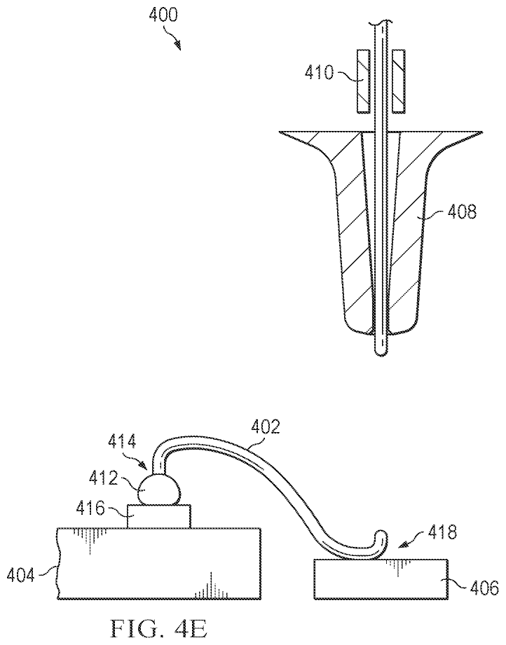

FIGS. 4A-4E illustrate a process 400 to attach wire bonds 402 to a die 404 and terminal leads 406 using a capillary instrument 408. In FIG. 4A, the wire bond 402 is clamped into the capillary instrument 408 via a wire clamp 410 and a ball bond (e.g., melted/molten wire bond material) 412 is attached to a first end 414 of the wire bond 402. In FIG. 4B, the capillary instrument 408 is lowered until the ball bond 412 contacts a bond pad 416 (the cavity is not shown for simplicity and clarity) on the die 404. In FIG. 4C, the capillary instrument 408 is raised away from the die 404 leaving the ball bond 412 and wire bond 402 attached to the bond pad 416. In FIG. 4D, the capillary instrument 408 is lowered onto the terminal lead 406 and attaches a second end 418 of the wire bond 402 to the terminal lead 406. In FIG. 4E, the wire bond 402 is cut and the capillary instrument is raised away from the terminal lead 406 leaving the second end 418 of the wire bond 402 attached to the terminal lead 406.

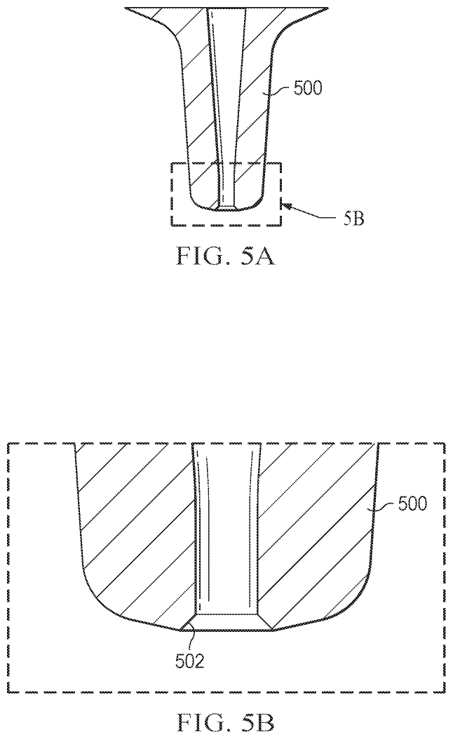

FIGS. 5A-5C, 6A-6C, and 7A-7C are illustrations of three different example capillary instrument tip configurations. When the ball bond is attached to the bond pad, force vectors are generated by the capillary instrument and are distributed toward the ball bond. The distribution of the force vectors across the ball bond, however, will vary based on the configuration of the capillary tip. For example, FIGS. 5A-5C illustrate one example of a capillary instrument 500 that includes a single inner chamfered tip configuration 502 (best illustrated in FIG. 5B). As illustrated in FIG. 5C, the force vectors 504 converge in a single central location as indicated by the intersection of the two force vectors 504. In the example illustrated in FIG. 5C, only two force vectors are illustrated for simplicity and clarity. It is understood, however, that the number of force vectors is greater than two. Thus, the example illustrated in FIG. 5C is for illustrative purposes only and is not intended to limit the scope of the invention. Therefore, when the bond ball is attached to the bond pad, the ball bond is not evenly distributed across the bond pad thereby causing gaps at the bond line (i.e., at an interface between the ball bond and the bond pad).

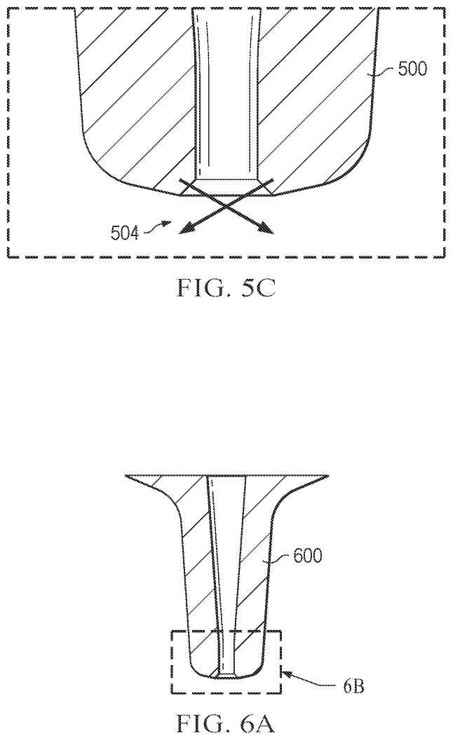

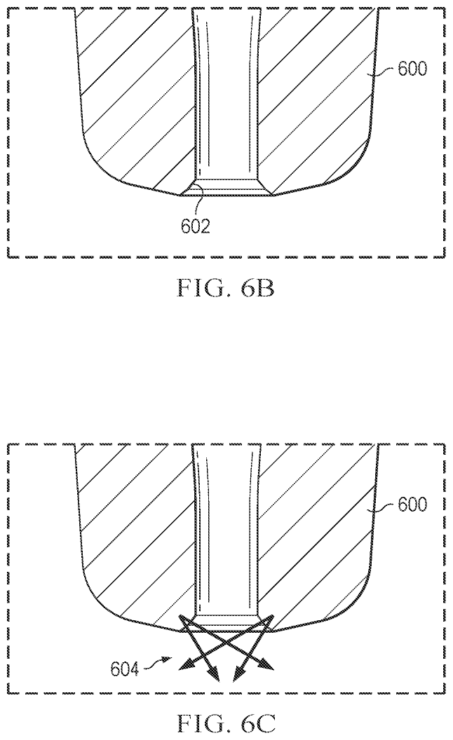

FIGS. 6A-6C illustrate another example of a capillary instrument 600 that includes a double inner chamfered tip configuration 602 (best illustrated in FIG. 6B). As illustrated in FIG. 6C, the force vectors 604 converge in a pair of locations as indicated by the intersection of the four force vectors 604. In the example illustrated in FIG. 6C, only four force vectors are illustrated for simplicity and clarity. It is understood, however, that the number of force vectors is greater than four. Thus, the example illustrated in FIG. 6C is for illustrative purposes only and is not intended to limit the scope of the invention. Therefore, in this example, when the bond ball is attached to the bond pad, the ball bond is more evenly distributed across the bond pad thereby mitigating the occurrence of cracks and gaps at the bond line (i.e., at an interface between the ball bond and the bond pad).

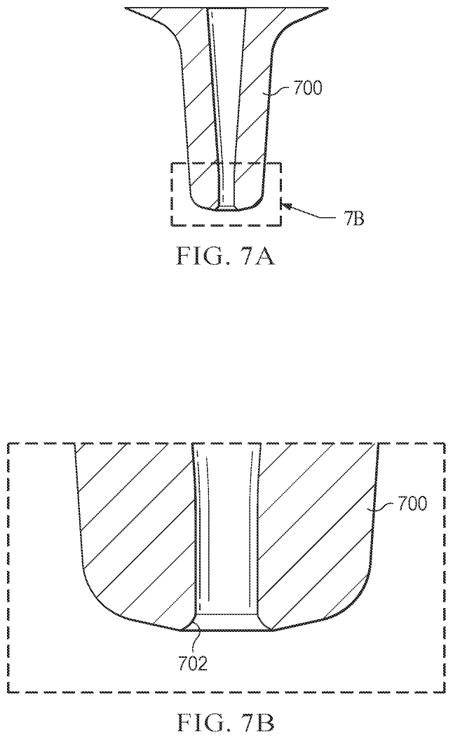

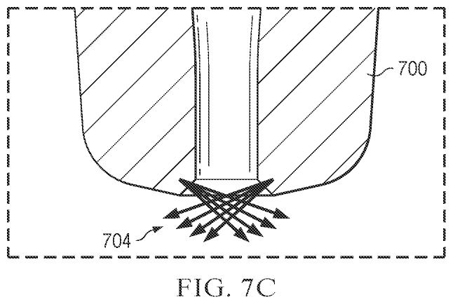

FIGS. 7A-7C illustrate another example of a capillary instrument 700 that includes a convex-shaped inner chamfered tip configuration 702 (best illustrated in FIG. 7B). As illustrated in FIG. 7C, the force vectors 704 converge in multiple locations as indicated by the intersection of the eight force vectors 704 due to the convex shape of the tip 702. In the example illustrated in FIG. 7C, only eight force vectors are illustrated for simplicity and clarity. It is understood, however, that the number of force vectors is greater than eight. Thus, the example illustrated in FIG. 7C is for illustrative purposes only and is not intended to limit the scope of the invention. Therefore, in this example, when the bond ball is attached to the bond pad, the ball bond is uniformly distributed across the bond pad thereby mitigating the occurrence of cracks and gaps at the bond line (i.e., at an interface between the ball bond and the bond pad).

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a substrate;
a die having an active surface, the die being disposed on the substrate;
bond pads disposed on the active surface of the die, the bond pads including a recess defined in a top surface of the bond pads;
ball bonds disposed in the recess of the bond pads;
wire bonds attached to the ball bonds and to the substrate; and
a mold compound encapsulating the die, the bond pads, and the ball bonds, the mold compound covering all but one surface of the substrate, where the one surface not covered faces away from the die.

2. The electronic device of claim 1, wherein an interface between the ball bonds and the bond pads forms a bond line substantially free from cracks and gaps.

3. The electronic device of claim 1, wherein the recess has a depth of approximately 1-3 μm and a width of approximately 30-110 μm.

4. The electronic device of claim 1, wherein the substrate is a leadframe that includes a die pad and conductive terminals, the die being attached to the die pad via a die attach material and the wire bonds being attached to the conductive terminals.

5. A method comprising:
providing a die having an active surface;
forming bond pads on the active surface of the die;
forming a recess in a top surface of the bond pads;
placing the die on a substrate;
attaching wire bonds from the bond pads to the substrate; and
forming a mold compound over the die.

6. The method of claim 5, wherein forming bond pads on an active surface of the die includes forming a photoresist material layer over the active surface of the die, the photoresist material layer having openings patterned therein, and depositing a metal plating layer in the openings of the photoresist material layer.

7. The method of claim 5, wherein forming a recess in a top surface of the bond pads includes performing an etching process to form the recess.

8. The method of claim 5, wherein forming a recess in a top surface of the bond pads includes performing a first electroplating process to form the bond pads and performing a second electroplating process to build up side walls of the bond pads to form the recess.

9. The method of claim 5, wherein attaching wire bonds from the bond pads to the substrate includes attaching a first end of the wire bonds to a ball bond, depositing the ball bond in the recess of the bond pads via a capillary instrument, and attaching a second end of the wire bonds to the substrate via the capillary instrument.

10. The method of claim 9, wherein attaching the wire bonds from the bond pads to the substrate is performed at a low temperature in a range of approximately 90° C.-120° C.

11. The method of claim 9, wherein the capillary instrument has a double inner chamfered tip to uniformly distribute force vectors across the ball bond while attaching the first end of the wire bond to the bond pads.

12. The method of claim 9, wherein the capillary instrument has a convex-shaped inner chamfered tip to uniformly distribute force vectors across the ball bond while attaching the first end of the wire bond to the bond pads.

13. The method of claim 9, wherein the mold compound encapsulates the die, the bond pads, the ball bonds, and the wire bonds, the mold compound covering all but one surface of the substrate, where the one surface not covered faces away from the die.

14. A method comprising:
fabricating a die assembly comprising:
providing a die having an active surface;
forming a photoresist material layer over the active surface of the die, the photoresist material layer having openings patterned therein;
depositing a metal plating layer in the openings of the photoresist material layer to form bond pads on the active surface of the die; and
forming a recess in a top surface of the bond pads;
placing the die on a die pad of a leadframe;
attaching wire bonds from the bond pads to the leadframe; and
forming a mold compound over the die.

15. The method of claim 14, wherein forming a recess in a top surface of the bond pads includes performing an etching process to form the recess.

16. The method of claim 14, wherein forming a recess in a top surface of the bond pads includes performing a first electroplating process to form the bond pads and performing a second electroplating process to build up side walls of the bond pads to form the recess.

17. The method of claim 14, wherein attaching the wire bonds from the bond pads to the leadframe is performed at a low temperature in a range of approximately 90° C.-120° C.

18. The method of claim 14, wherein attaching wire bonds from the bond pads to the leadframe includes attaching a first end of the wire bonds to a ball bond, depositing the ball bond in the recess of the bond pads via a capillary instrument, and attaching a second end of the wire bonds to the leadframe via the capillary instrument.

19. The method of claim 18, wherein the capillary instrument has a double inner chamfered tip to uniformly distribute force vectors across the ball bond while attaching the first end of the wire bond to the bond pads.

20. The method of claim 18. wherein the capillary instrument has a convex-shaped inner chamfered tip to uniformly distribute force vectors across the ball bond while attaching the first end of the wire bond to the bond pads.
